(19) United States
(12) Patent Application Publication
(10) Pub. No.: US 2025/0316576 A1
(43) Pub. Date: Oct. 9, 2025

(54) SEMICONDUCTOR DEVICE AND METHOD FOR MANUFACTURING SEMICONDUCTOR DEVICE

(71) Applicant: Rohm Co., Ltd., Kyoto (JP)

(72) Inventor: Hiroki MIYAZAKI, Kyoto (JP)

(21) Appl. No.: 19/243,968

(22) Filed: Jun. 20, 2025

Related U.S. Application Data
(63) Continuation of application No. PCT/JP2023/044442, filed on Dec. 12, 2023.

(30) Foreign Application Priority Data
Dec. 27, 2022 (JP) 2022-209407

(51) Int. Cl. H01L 23/498; H01L 21/48; H01L 21/56; H01L 23/00; H01L 23/31

(52) U.S. Cl. CPC H01L 23/49838; H01L 21/4853; H01L 21/565; H01L 21/568; H01L 23/3121; H01L 23/49805; H01L 23/49866; H01L 24/13; H01L 24/16; H01L 24/81; H01L 2224/13111; H01L 2224/1312; H01L 2224/13139; H01L 2224/16113; H01L 2224/81005; H01L 2224/81385; H01L 2224/81447; H01L 2224/81455; H01L 2224/81466; H01L 2224/81815

(57) ABSTRACT

A semiconductor device includes: a conductive layer; a semiconductor element including an electrode located on one side in a first direction; and a bonding layer electrically bonding the conductive layer and the semiconductor element. The conductive layer includes an obverse surface facing the semiconductor element in the first direction, and a pedestal portion protruding from the obverse surface. The bonding layer includes a portion located between the pedestal portion and the electrode. The pedestal portion includes a first surface that is an interface with the obverse surface, and a second surface that faces a same side as the obverse surface in the first direction and that is in contact with the bonding layer. An area of the second surface is larger than an area of the first surface. As viewed in the first direction, a periphery of the second surface surrounds the first surface.

### TECHNICAL FIELD

The present disclosure relates to a semiconductor device and a method for manufacturing the same.

### BACKGROUND ART

JP-A-2020-77694 discloses an example of a semiconductor device including a flip-chip mounted semiconductor element. In the semiconductor device, an electrode of the semiconductor element is electrically bonded by flip-chip bonding to a lead via a bonding layer such as solder. This reduces the length of the conductive path between the semiconductor element and the lead, allowing the reduction of parasitic inductance in the semiconductor device, for example.

The semiconductor device disclosed in JP-A-2020-77694 is provided with a plurality of leads including a plurality of first leads and a plurality of second leads. When the electrode of the semiconductor element is electrically bonded to one of the first leads, the wetting and spreading of the bonding layer may become excessive, and the bonding layer may reach one of the second leads as a result. If the bonding layer reaches one of the second leads, a short circuit will occur in the conductive path of the semiconductor device. Thus, there is a demand for suppressing excessive wetting and spreading of the bonding layer.

### BRIEF DESCRIPTION OF THE DRAWINGS

FIG. 1 is a plan view illustrating a semiconductor device according to a first embodiment of the present disclosure.

FIG. 2 is a plan view corresponding to FIG. 1, as seen through a semiconductor element and a sealing resin.

FIG. 3 is a bottom view illustrating the semiconductor device in FIG. 1.

FIG. 4 is a cross-sectional view taken along line IV-IV in FIG. 2.

FIG. 5 is a cross-sectional view taken along line V-V in FIG. 2.

FIG. 6 is a cross-sectional view taken along line VI-VI in FIG. 2.

FIG. 7 is a partially enlarged view of FIG. 2.

FIG. 8 is a cross-sectional view taken along line VIII-VIII in FIG. 7.

FIG. 9 is a cross-sectional view illustrating a manufacturing process of the semiconductor device shown in FIG. 1.

FIG. 10 is a cross-sectional view illustrating a manufacturing process of the semiconductor device shown in FIG. 1.

FIG. 11 is a cross-sectional view illustrating a manufacturing process of the semiconductor device shown in FIG. 1.

FIG. 12 is a cross-sectional view illustrating a manufacturing process of the semiconductor device shown in FIG. 1.

FIG. 13 is a cross-sectional view illustrating a manufacturing process of the semiconductor device shown in FIG. 1.

FIG. 14 is a partially enlarged cross-sectional view illustrating a manufacturing process of the semiconductor device shown in FIG. 1.

FIG. 15 is a partially enlarged cross-sectional view illustrating a manufacturing process of the semiconductor device shown in FIG. 1.

FIG. 16 is a partially enlarged cross-sectional view illustrating a manufacturing process of the semiconductor device shown in FIG. 1.

FIG. 17 is a partially enlarged cross-sectional view illustrating a manufacturing process of the semiconductor device shown in FIG. 1.

FIG. 18 is a cross-sectional view illustrating a manufacturing process of the semiconductor device shown in FIG. 1.

FIG. 19 is a cross-sectional view illustrating a manufacturing process of the semiconductor device shown in FIG. 1.

FIG. 20 is a cross-sectional view illustrating a manufacturing process of the semiconductor device shown in FIG. 1.

FIG. 21 is a cross-sectional view illustrating a manufacturing process of the semiconductor device shown in FIG. 1.

FIG. 22 is a cross-sectional view illustrating a manufacturing process of the semiconductor device shown in FIG. 1.

FIG. 23 is a cross-sectional view illustrating a manufacturing process of the semiconductor device shown in FIG. 1.

FIG. 24 is a partially enlarged plan view illustrating a semiconductor device according to a second embodiment of the present disclosure, as seen through a semiconductor element and a sealing resin.

FIG. 25 is a cross-sectional view taken along line XXV-XXV in FIG. 24.

FIG. 26 is a bottom view illustrating a semiconductor element in a semiconductor device according to a third embodiment of the present disclosure.

FIG. 27 is a partially enlarged cross-sectional view illustrating the semiconductor device shown in FIG. 26.

### DETAILED DESCRIPTION OF EMBODIMENTS

Embodiments of the present disclosure will be described with reference to the accompanying drawings.

### First Embodiment

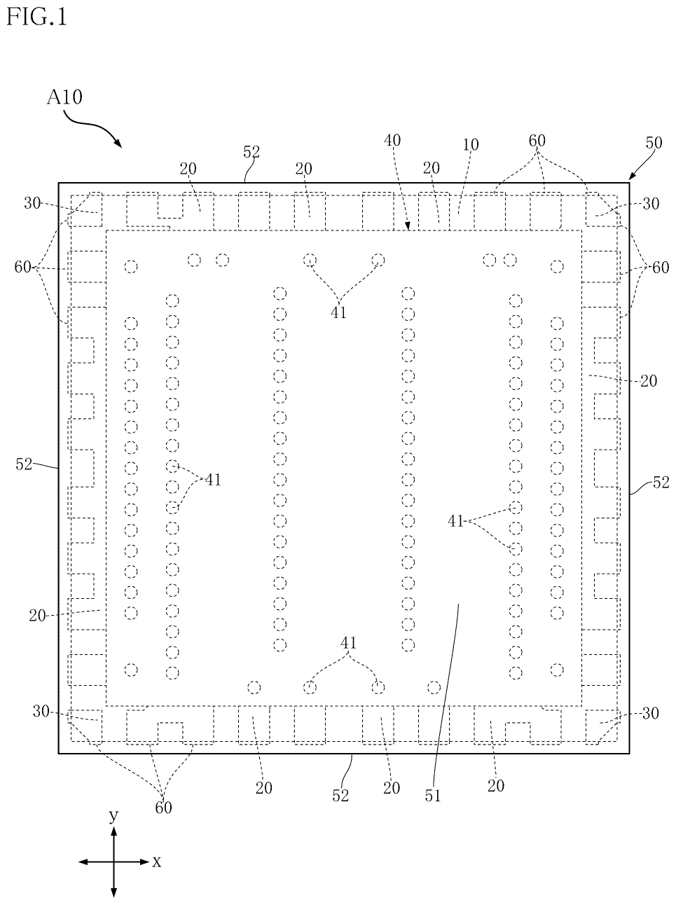

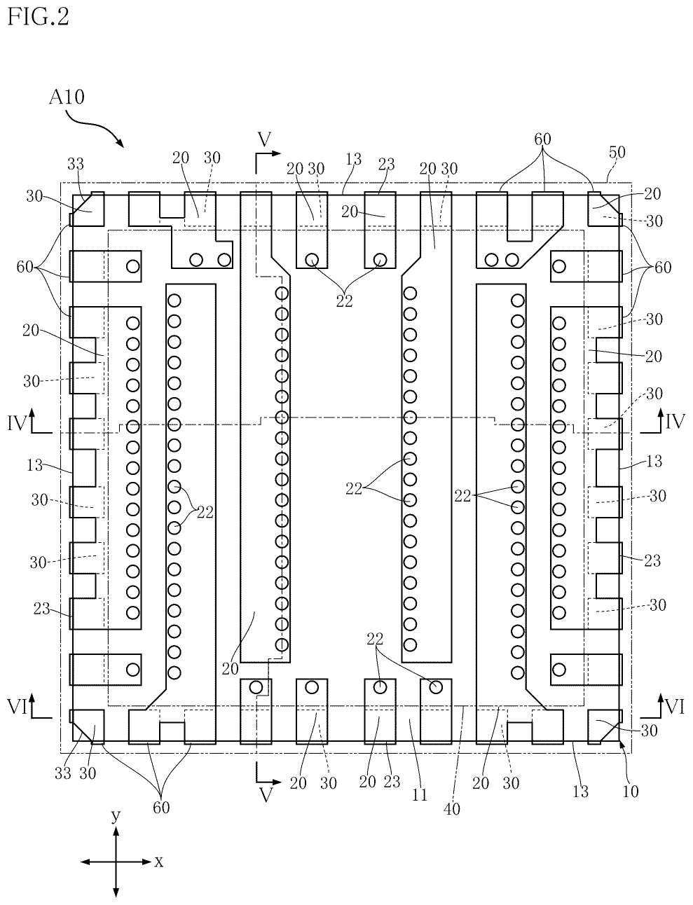

The following describes a semiconductor device A10 according to a first embodiment of the present disclosure, with reference to FIGS. 1 to 8. The semiconductor device A10 includes a substrate 10, a plurality of conductive layers 20, a plurality of bonding layers 29, a plurality of terminals 30, a semiconductor element 40, a sealing resin 50, and a plurality of covering layers 60. The semiconductor device A10 is provided in a resin package for surface-mounting onto a wiring board. The resin package is a quad flat non-leaded (QFN) package where a plurality of leads do not protrude from the sealing resin 50. For convenience of understanding, FIG. 1 shows the sealing resin 50 as transparent. FIG. 2 corresponds to FIG. 1, but shows the semiconductor element 40 and the sealing resin 50 as transparent to facilitate understanding. FIG. 2 shows the semiconductor element 40 and the sealing resin 50 with imaginary lines (two-dot chain lines).

FIG. 2 also shows lines IV-IV, V-V, and VI-VI with single-dot chain lines. In the description of the semiconductor device A10, an example of the direction that is normal to a mounting surface 11 (described below) of the substrate 10 is referred to as a “first direction z” for convenience. An example of a direction perpendicular to the first direction z is referred to as a “second direction x”. An example of the direction perpendicular to the first direction z and the second direction x is referred to as a “third direction y”. As shown in FIG. 1, the semiconductor device A10 has a rectangular shape as viewed in the first direction z.

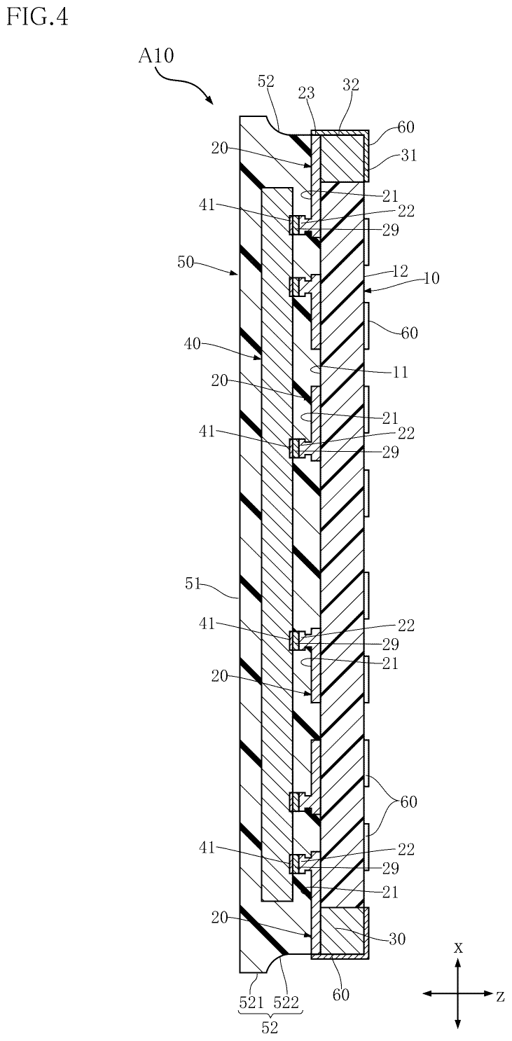

As shown in FIGS. 4 to 6, the substrate 10 supports the conductive layers 20 and the sealing resin 50. The substrate 10 is electrically insulative. The substrate 10 may be made of black epoxy resin, for example. The substrate 10 has a mounting surface 11, a reverse surface 12, and a plurality of first side surfaces 13. The mounting surface 11 and the reverse surface 12 face away from each other in the first direction z. The mounting surface 11 faces the conductive layers 20. The reverse surface 12 is exposed to the outside. When the semiconductor device A10 is mounted onto a wiring board, the reverse surface 12 faces the wiring board. Each of the first side surfaces 13 faces in a direction perpendicular to the first direction z. The first side surfaces 13 are connected to the mounting surface 11 and the reverse surface 12. The first side surfaces 13 include two first side surfaces 13 facing in the second direction x, and two first side surfaces 13 facing in the third direction y.

As shown in FIGS. 4 to 6, the conductive layers 20 are disposed on the mounting surface 11 of the substrate 10. The conductive layers 20 and the terminals 30 form the conductive paths between the semiconductor element 40 and the wiring board on which the semiconductor device A10 is mounted.

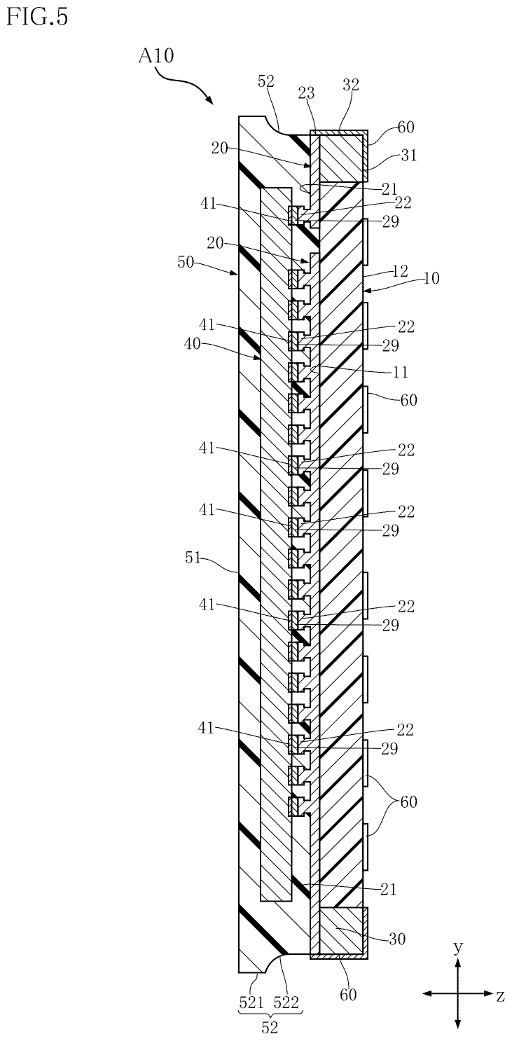

As shown in FIGS. 4 and 5, each of the conductive layers 20 has an end surface 23. The end surface 23 faces in a direction perpendicular to the first direction z. The end surface 23 is exposed from a second region 522 of one of a plurality of second side surfaces 52 (described below) of the sealing resin 50.

As shown in FIGS. 2, 4, and 5, each of the conductive layers 20 has an obverse surface 21. The obverse surface 21 faces the semiconductor element 40 in the first direction z.

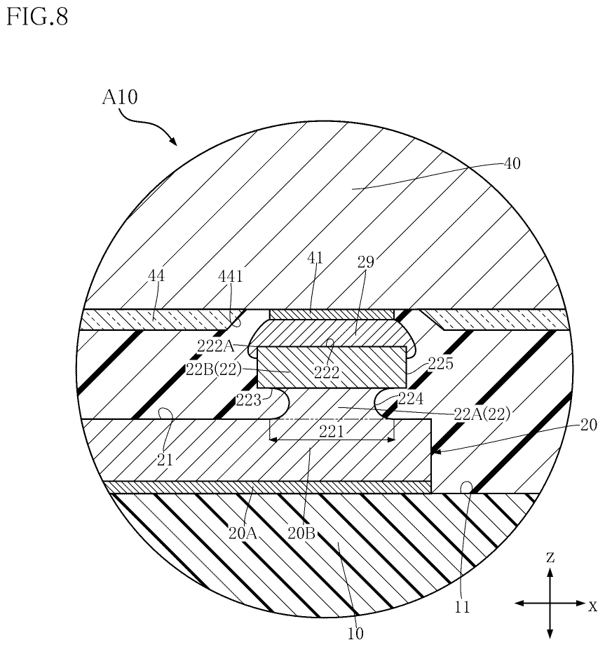

As shown in FIG. 8, each of the conductive layers 20 has an underlying layer 20A and a body layer 20B. The underlying layer 20A is in contact with the mounting surface 11 of the substrate 10. The underlying layer 20A contains titanium (Ti) and copper (Cu). The body layer 20B is stacked on the underlying layer 20A. The body layer 20B includes the obverse surface 21. The dimension of the body layer 20B in the first direction z is larger than the dimension of the underlying layer 20A in the first direction z. The body layer 20B contains copper.

As shown in FIGS. 2, 4, and 5, each of the conductive layers 20 has at least one pedestal portion 22. The pedestal portion 22 protrudes from the obverse surface 21 of one of the conductive layers 20 in the first direction z. The pedestal portion 22 is connected to the body layer 20B.

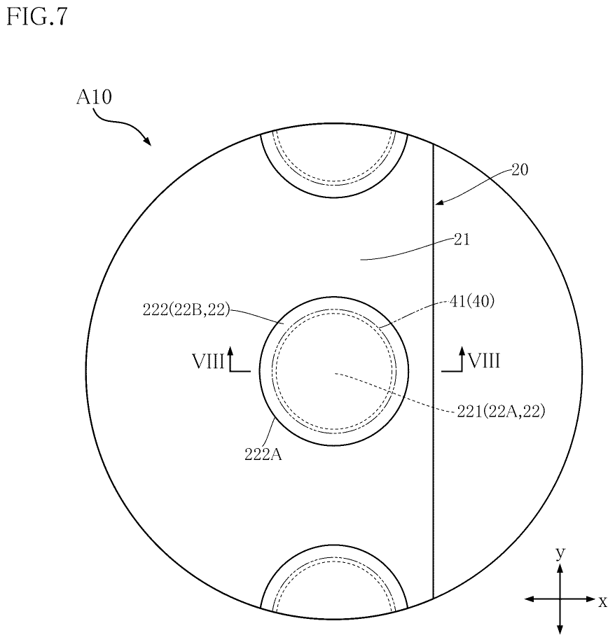

As shown in FIG. 8, the pedestal portion 22 has a first surface 221 and a second surface 222. The first surface 221 is an interface with the obverse surface 21 of one of the conductive layers 20. The first surface 221 faces the mounting surface 11 of the substrate 10 in the first direction z. The second surface 222 faces the same side as the obverse surface 21 in the first direction z. Thus, the second surface 222 faces the opposite side from the first surface 221 in the first direction z. As shown in FIG. 7, the area of the second surface 222 is larger than that of the first surface 221. As viewed in the first direction z, a periphery 222A of the second surface 222 surrounds the first surface 221.

As shown in FIG. 8, the pedestal portion 22 has a first portion 22A and a second portion 22B. The first portion 22A includes the first surface 221. The second portion 22B includes the second surface 222, and is connected to the first portion 22A. The first portion 22A contains copper. The metal contained in the first portion 22A is the same as the metal contained in the body layer 20B of each conductive layer 20. The second portion 22B contains nickel (Ni). The degree of erosion of the second portion 22B caused by the bonding layer 29 is smaller than that of erosion of the first portion 22A caused by the bonding layer 29.

As shown in FIG. 8, the second portion 22B of the pedestal portion 22 protrudes from the first portion 22A of the pedestal portion 22 in a direction perpendicular to the first direction z. The second portion 22B includes a third surface 223. The third surface 223 faces the obverse surface 21 of one of the conductive layers 20 in the first direction z. The third surface 223 is positioned outside the interface between the first portion 22A and the second portion 22B of the pedestal portion 22 as viewed in the first direction z. As viewed in the first direction z, the third surface 223 overlaps with the first surface 221. The third surface 223 is covered with the sealing resin 50.

As shown in FIG. 8, the first portion 22A of the pedestal portion 22 includes a fourth surface 224. The fourth surface 224 is positioned between the first surface 221 and the third surface 223 in the first direction z. The fourth surface 224 is curved toward the inside of the first portion 22A. The fourth surface 224 is covered with the sealing resin 50.

As shown in FIG. 8, the second portion 22B of the pedestal portion 22 includes a fifth surface 225. The fifth surface 225 faces in a direction perpendicular to the first direction z. The fifth surface 225 is connected to the second surface 222 and the third surface 223.

As shown in FIGS. 4 to 6, a part of each terminal 30 is accommodated in the substrate 10. Each of at least some of the terminals 30 is connected to one of the conductive layers 20. The terminals 30 contain copper.

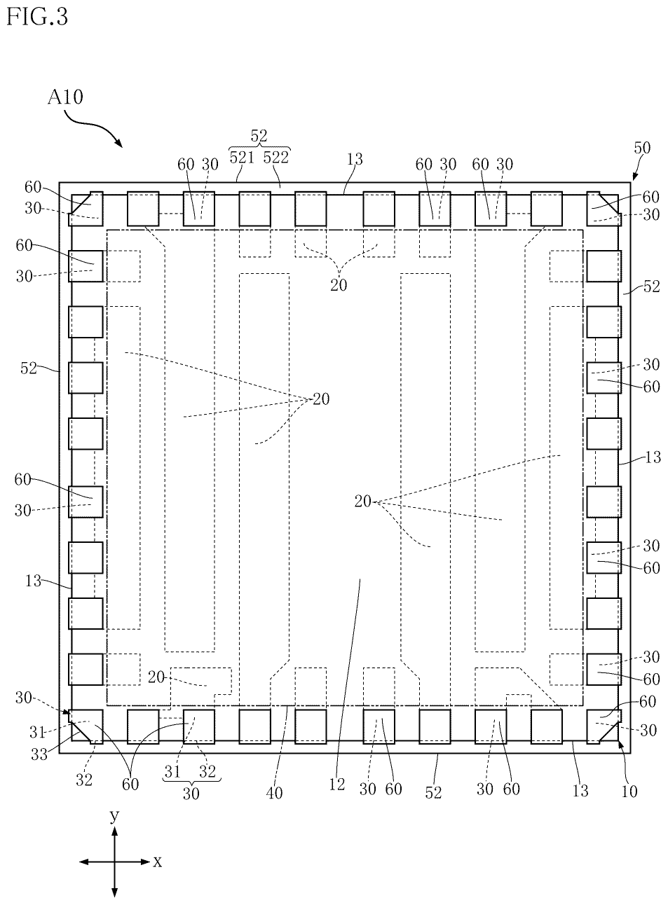

As shown in FIGS. 3 to 5, each of the terminals 30 has a first exposed surface 31 and a second exposed surface 32. The first exposed surface 31 faces the same side as the reverse surface 12 of the substrate 10 in the first direction z. The first exposed surface 31 is exposed from the reverse surface 12. The second exposed surface 32 faces in a direction perpendicular to the first direction z. The second exposed surface 32 is exposed from one of the first side surfaces 13 of the substrate 10. The second exposed surface 32 is flush with the end surface 23 of one of the conductive layers 20.

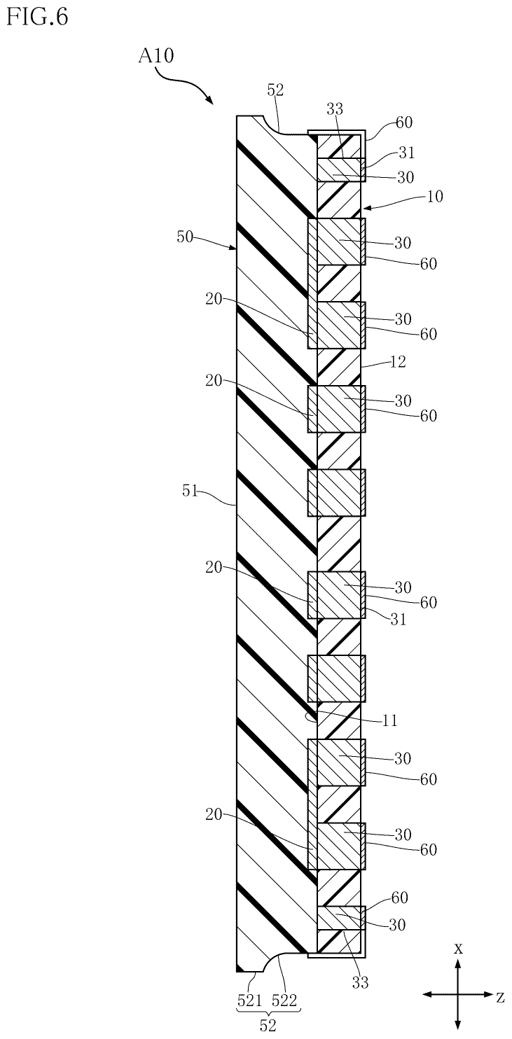

As shown in FIGS. 2 and 6, the plurality of terminals 30 include four terminals 30 respectively located at the four corners of the substrate 10 as viewed in the first direction z, and each of the four terminals 30 has an inclined end surface 33. The inclined end surface 33 is connected to the first exposed surface 31 and the second exposed surface 32. The inclined end surface 33 faces outward from the semiconductor device A10. A normal line of the inclined end surface 33 is inclined to each of the second direction x and the third direction y. The inclined end surface 33 is covered with the substrate 10. Some of the four terminals 30 each having an inclined end surface 33 are spaced apart from the conductive layers 20.

As shown in FIGS. 4 and 5, the semiconductor element 40 is electrically bonded to the pedestal portions 22 of the conductive layers 20 via the bonding layers 29. The semiconductor element 40 has a plurality of electrodes 41.

As shown in FIGS. 4 and 5, the electrodes 41 are positioned on a surface of the semiconductor element 40 in the first direction z. Each of the electrodes 41 faces the pedestal portion 22 of one of the conductive layers 20.

As shown in FIG. 8, the semiconductor element 40 has a passivation film 44. The passivation film 44 covers the surface of the semiconductor element 40 positioned on the side facing the mounting surface 11 of the substrate 10 in the first direction z. The passivation film 44 is electrically insulative. The passivation film 44 is formed with a plurality of openings 441. The electrodes 41 are accommodated in the respective openings 441. The passivation film 44 is made of a material containing polyimide.

As shown in FIGS. 4 and 5, each of the bonding layers 29 electrically bonds the pedestal portion 22 of one of the conductive layers 20 and one of the electrodes 41 of the semiconductor element 40. As a result, the semiconductor element 40 is electrically connected to the conductive layers 20. The bonding layers 29 contain tin (Sn) and silver (Ag). Alternatively, the bonding layers 29 may contain tin and antimony (Sb).

As shown in FIG. 8, each of the bonding layers 29 includes a portion located between the pedestal portion 22 of one of the conductive layers 20 and one of the electrodes 41 of the semiconductor element 40. The bonding layer 29 is in contact with the second surface 222 of the pedestal portion 22. The bonding layer 29 is also in contact with the fifth surface 225 of the pedestal portion 22. The third surface 223 of the pedestal portion 22 is spaced apart from the bonding layer 29.

As shown in FIGS. 4 and 5, the sealing resin 50 covers a part of each conductive layer 20 and the semiconductor element 40. As shown in FIG. 8, the sealing resin 50 is in contact with the bonding layers 29. The sealing resin 50 is electrically insulative. The sealing resin 50 may be made of black epoxy resin, for example.

As shown in FIGS. 4 to 6, the sealing resin 50 has a top surface 51 and a plurality of second side surfaces 52. The top surface 51 faces the same side as the mounting surface 11 of the substrate 10 in the first direction z. The second side surfaces 52 are connected to the top surface 51. Each of the second side surfaces 52 includes a first region 521 and a second region 522. The first region 521 is connected to the top surface 51, and faces in a direction perpendicular to the first direction z. The second region 522 is positioned opposite from the top surface 51 with respect to the first region 521 in the first direction z, and is connected to the first region 521. The second region 522 is curved toward the inside of the sealing resin 50. As viewed in the first direction z, the second region 522 overlaps with the top surface 51.

As shown in FIGS. 2 and 3, the covering layers 60 are exposed to the outside. As shown in FIGS. 3 and 5, each of the covering layers 60 covers the first exposed surface 31 and the second exposed surface 32 of a terminal 30. Some of the covering layers 60 cover the end surfaces 23 of the respective conductive layers 20.

The covering layers 60 are conductors. The semiconductor device A10 is mounted onto a wiring board by electrically bonding the covering layers 60 to the wiring board via solder. Each of the covering layers 60 includes a plurality of metal layers. The metal layers are stacked in the order of a nickel layer and a gold (Au) layer, starting from the side closer to one of the terminals 30. Alternatively, the plurality of metal layers may be stacked in the order of a nickel layer, a palladium (Pd) layer, and a gold layer, starting from the side closer to one of the terminals 30. Thus, the composition of the covering layers 60 includes gold.

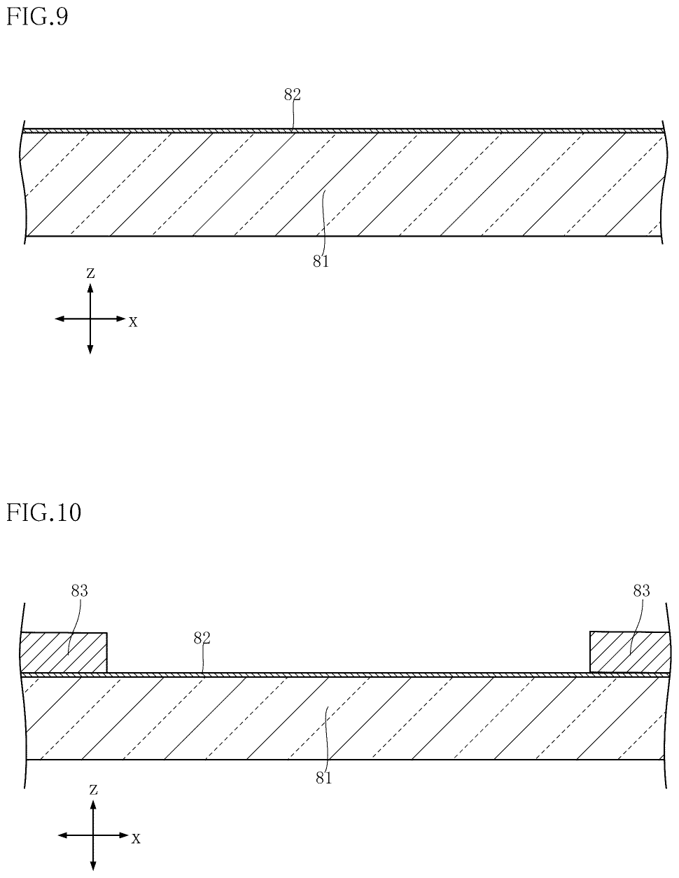

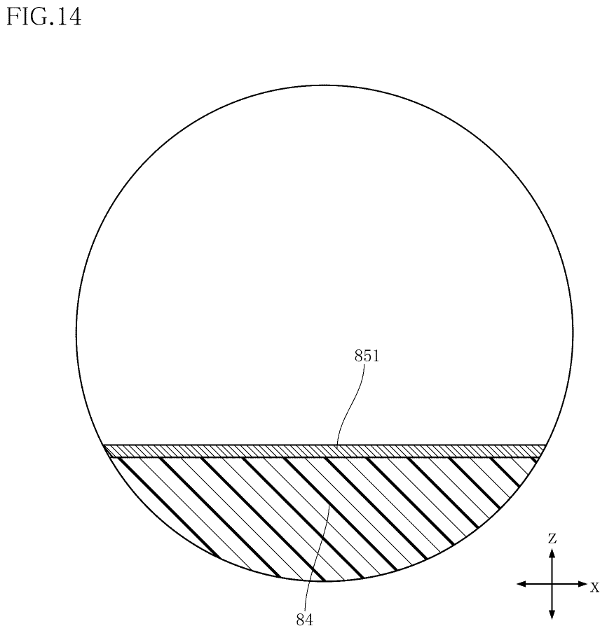

Next, an example of a method for manufacturing the semiconductor device A10 will be described with reference to FIGS. 9 to 23. Note that FIGS. 9 to 13 and FIGS. 18 to 22 are sectional views taken along the same (or substantially the same) line as in FIG. 4. FIGS. 14 to 17 are sectional views taken along the same (or substantially the same) line as in FIG. 8. First, as shown in FIG. 9, an intermediate layer 82 is formed to cover a surface of a support member 81 in the first direction z. The intermediate layer 82 is made up of a first metal thin film, which is in contact with the support member 81 and is made of titanium, and a second metal thin film, which is formed on the first metal thin film and is made of copper. The intermediate layer 82 is formed by depositing these metal thin films by sputtering.

Next, as shown in FIG. 10, a plurality of terminal layers 83 are formed to protrude from the intermediate layer 82 in the first direction z. Parts of the terminal layers 83 will become the terminals 30 of the semiconductor device A10. In the formation of the terminal layers 83, lithographic patterning is performed on the intermediate layer 82. Next, electrolytic plating is performed with the intermediate layer 82 serving as a conductive path, so that the terminal layers 83 are deposited. Finally, a mask layer used for the lithographic patterning is removed. As a result, the terminal layers 83 are formed.

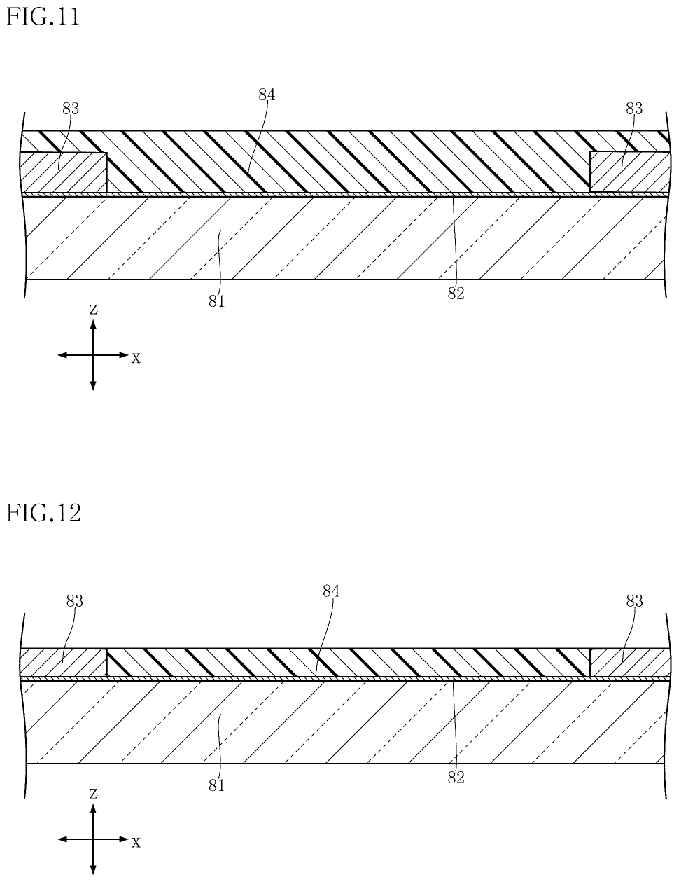

Next, as shown in FIG. 11, a first resin layer 84 is formed to cover the terminal layers 83. A part of the first resin layer 84 will become the substrate 10 of the semiconductor device A10. The first resin layer 84 is made of a material containing black epoxy resin. The first resin layer 84 is formed by compression molding. In this case, the first resin layer 84 is formed to be in contact with the intermediate layer 82 and to cover the entirety of the terminal layers 83.

Next, as shown in FIG. 12, a part of each terminal layer 83 and a part of the first resin layer 84 are removed by grinding. These parts to be removed are those positioned opposite from the side facing the intermediate layer 82 in the first direction z. As a result, the terminal layers 83 are exposed from the surface of the first resin layer 84 facing in the first direction z.

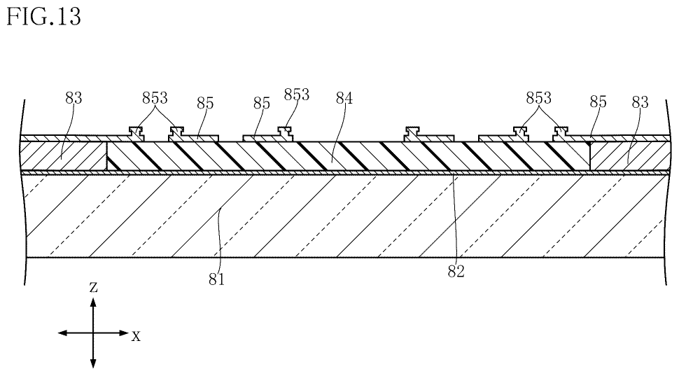

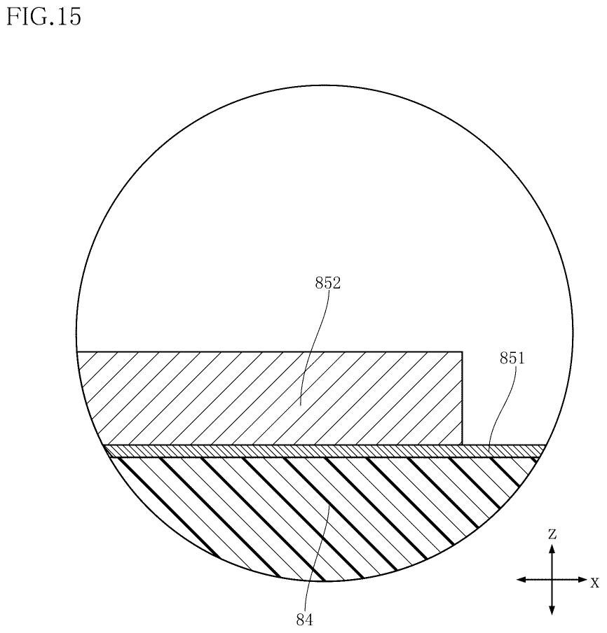

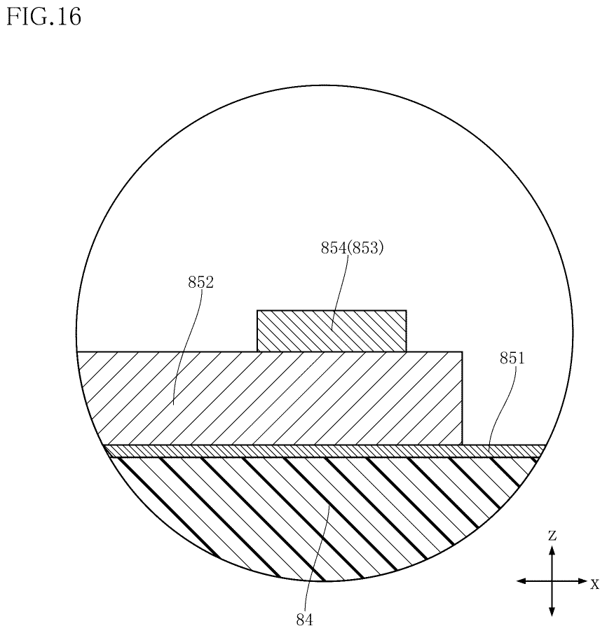

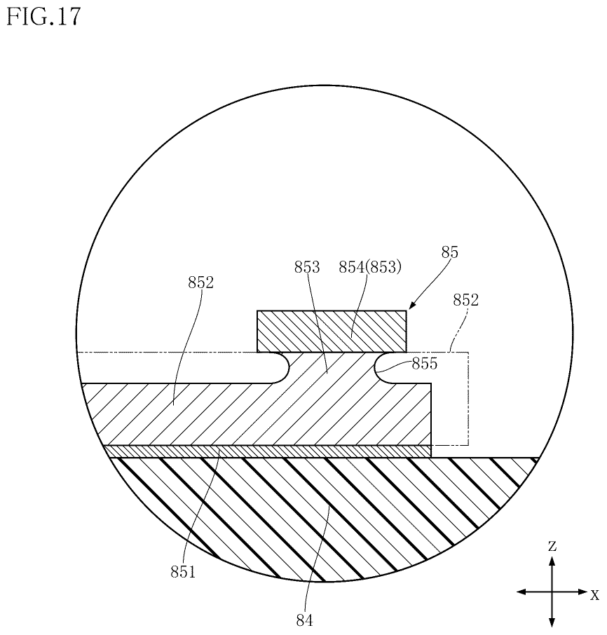

Next, as shown in FIG. 13, a plurality of conductive layers 85 are formed such that the conductive layers 85 are in contact with the surface of the first resin layer 84 facing in the first direction z and that each of the conductive layers 85 is connected to at least one of the terminal layers 83. The conductive layers 85 will become the conductive layers 20 and the bonding layers 29 in the semiconductor device A10. The step of forming each of the conductive layers 85 includes a step of forming an underlying layer 851 shown in FIG. 14, a step of forming a body layer 852 shown in FIG. 15, and a step of forming a pedestal portion 853 shown in FIGS. 16 and 17.

First, as shown in FIG. 14, the underlying layer 851 is formed to cover the entirety of the terminal layers 83 positioned opposite from the side facing the intermediate layer 82 (see FIG. 13) in the first direction z and to cover the entirety of the first resin layer 84. The underlying layer 851 is made of the same metal thin film as the intermediate layer 82. Thus, the underlying layer 851 contains titanium and copper. The underlying layer 851 is formed by sputtering.

Next, the body layer 852 is formed as shown in FIG. 15. To begin the formation of the body layer 852, lithographic patterning is performed on the underlying layer 851. Next, electrolytic plating is performed with the underlying layer 851 serving as a conductive path, so that the body layer 852 is formed on the underlying layer 851. The body layer 852 contains copper. Finally, a mask layer used for the lithographic patterning is removed.

Next, the pedestal portion 853 is formed to protrude from the body layer 852 in the first direction z. The step of forming the pedestal portion 853 includes a step of forming a protruding layer 854 shown in FIG. 16, and a step of forming a constricted portion 855 in the pedestal portion 853 shown in FIG. 17.

First, as shown in FIG. 16, the protruding layer 854 is formed to protrude from the body layer 852 in the first direction z. To begin the formation of the protruding layer 854, lithographic patterning is performed on the underlying layer 851 and the body layer 852. Next, electrolytic plating is performed with the underlying layer 851 and the body layer 852 serving as a conductive path, so that the protruding layer 854 is formed on the body layer 852. The protruding layer 854 includes a nickel layer, and an alloy layer formed on the nickel layer and containing tin. Finally, a mask layer used for the lithographic patterning is removed.

Next, as shown in FIG. 17, the constricted portion 855 is formed in the pedestal portion 853 such that the pedestal portion 853 is recessed in a direction perpendicular to the first direction z. The constricted portion 855 is connected to the body layer 852. In the formation of the constricted portion 855, a part of the underlying layer 851, which is exposed from the body layer 852 to the outside, is removed. The removal of the part of the underlying layer 851 is carried out by wet etching using a mixed solution of sulfuric acid (H₂SO₄) and hydrogen peroxide (H₂O₂). In this case, the part of the underlying layer 851 exposed from the body layer 852 to the outside, as well as a part of the area of the body layer 852 in contact with the protruding layer 854, is removed by increasing the time in which the body layer 852 is immersed in the solution. At this point, the protruding layer 854 retains its original shape. As a result, the constricted portion 855 is formed in the pedestal portion 853. The formation of the pedestal portion 853 is thereby completed, and the conductive layers 85 are formed through the above process.

Next, as shown in FIG. 18, each of the electrodes 41 of the semiconductor element 40 is electrically bonded to the pedestal portion 853 of one of the conductive layers 85. The electrical bonding is performed by flip-chip bonding. First, each of the electrodes 41 of the semiconductor element 40 is temporarily attached to the pedestal portion 853 of one of the conductive layers 85. Next, the alloy layer in the protruding layer 854 of each pedestal portion 853 is melted by reflow. Finally the melted alloy layer is solidified by cooling. As a result, the semiconductor element 40 is electrically bonded to the conductive layers 85. The alloy layers of the respective pedestal portions 853 are melted and solidified through the above process, and become the bonding layers 29 of the semiconductor device A10. The parts of the conductive layers 85 excluding the bonding layers 29 serve as the conductive layers 20 of the semiconductor device A10.

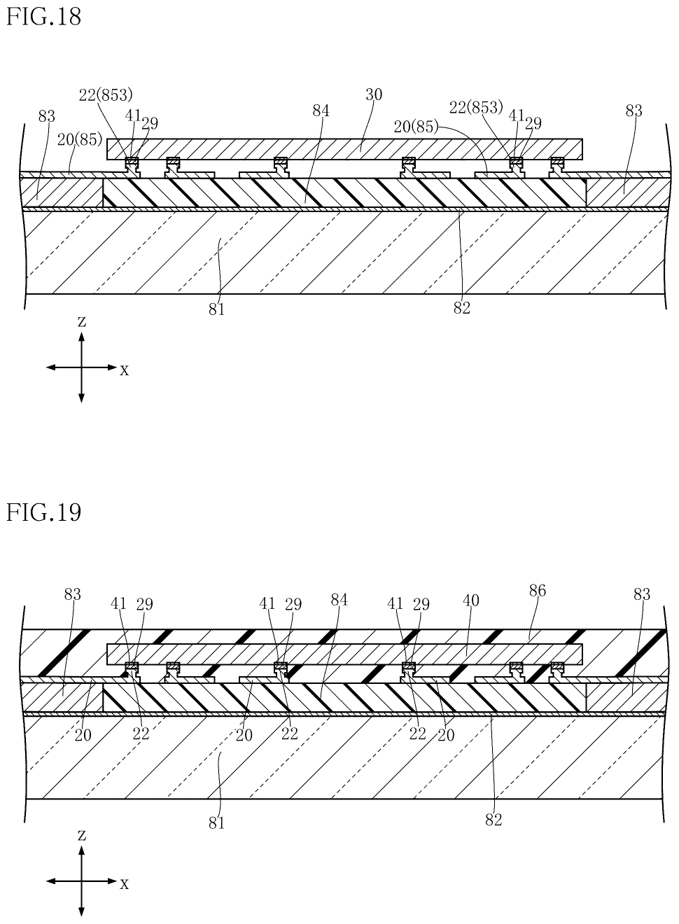

Next, as shown in FIG. 19, a second resin layer 86 is formed to cover the conductive layers 20 and the semiconductor element 40. A part of the second resin layer 86 will become the sealing resin 50 of the semiconductor device A10. The second resin layer 86 is made of a material containing black epoxy resin. The second resin layer 86 is formed by compression molding.

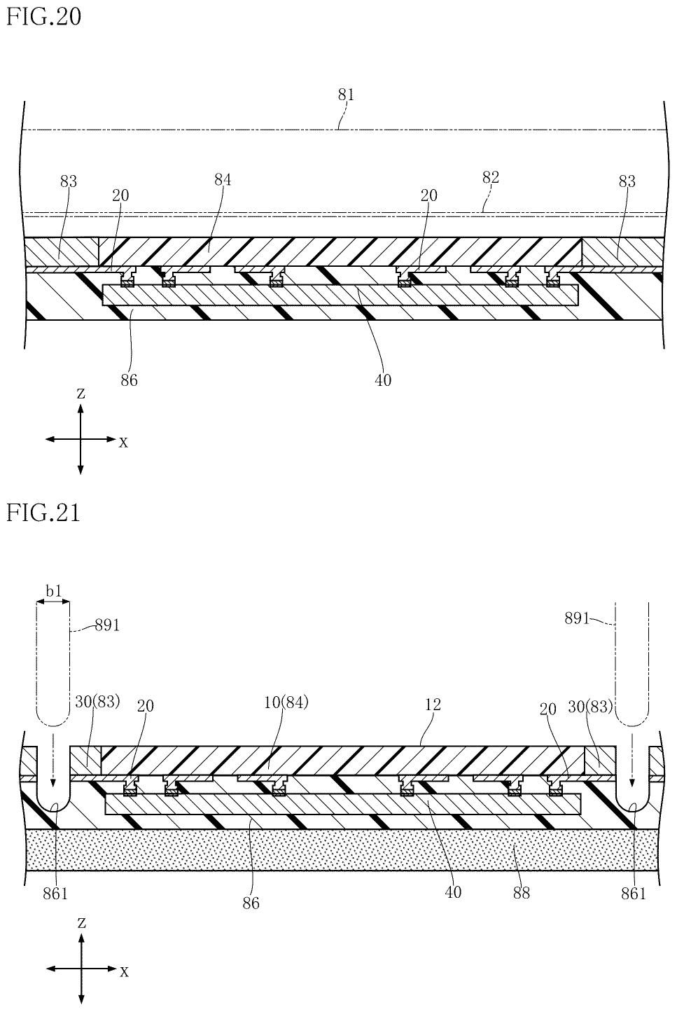

Next, as shown in FIG. 20, the support member 81 and the intermediate layer 82 are removed by grinding. At this point, a part of each terminal layer 83 and a part of the first resin layer 84 are removed by grinding.

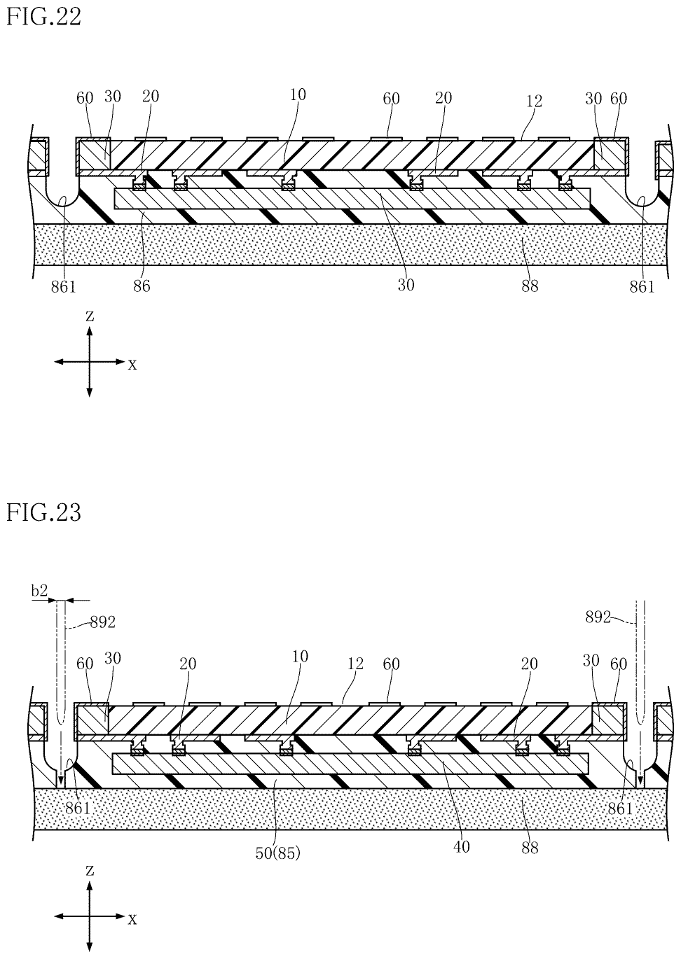

Next, as shown in FIG. 21, a tape 88 is attached to a surface of the second resin layer 86 facing in the first direction z. The tape 88 is a dicing tape. Then, a first blade 891 having a width b1 is used to remove a part of each terminal layer 83, a part of the first resin layer 84, a part of each conductive layer 20, and a part of the second resin layer 86 so as to form a plurality of grooves 861 that are recessed in the first direction z. The grooves 861 are formed in a lattice pattern along the second direction x and the third direction y.

Next, wet etching is performed to smooth the surfaces of the terminal layers 83 exposed to the outside from the first resin layer 84. As a result, the terminal layers 83 become the terminals 30 of the semiconductor device A10. At the same time, the first resin layer 84 becomes the substrate 10 of the semiconductor device A10. The surface of the substrate 10 that faces in the first direction z and is exposed to the outside is the reverse surface 12 of the substrate 10.

Next, as shown in FIG. 22, the covering layers 60 are formed to cover the surfaces of the respective terminals 30 exposed from the substrate 10 to the outside. The covering layers 60 are formed by electroless plating.

Finally, as shown in FIG. 23, a second blade 892 having a width b2 is used to cut the second resin layer 86. The width b2 is smaller than the width b1 of the first blade 891. When the second resin layer 86 is cut, the second blade 892 is passed through each of the grooves 861, and then the second blade 892 is moved in the first direction z until the second blade 892 touches the tape 88. With this step, the second resin layer 86 becomes the sealing resin 50 of the semiconductor device A10. As a result, the semiconductor device A10 is obtained.

The following describes advantages of the semiconductor device A10.

The semiconductor device A10 includes a conductive layer 20 having an obverse surface 21 and a pedestal portion 22, a semiconductor element 40 having an electrode 41, and a bonding layer 29 electrically bonding the conductive layer 20 and the electrode 41. The bonding layer 29 includes a portion located between the pedestal portion 22 and the electrode 41. The pedestal portion 22 has a first surface 221 that is an interface with the obverse surface 21, and a second surface 222 that faces the same side as the obverse surface 21 in the first direction z and that is in contact with the bonding layer 29. The area of the second surface 222 is larger than that of the first surface 221. As viewed in the first direction z, a periphery 222A of the second surface 222 surrounds the first surface 221. With this configuration, when the electrode 41 is electrically bonded to the pedestal portion 22 of the conductive layer 20 via the bonding layer 29, the melted bonding layer 29 is subjected to a larger surface tension at the periphery 222A of the second surface 222. This prevents the melted bonding layer 29 from overflowing from the periphery 222A of the second surface 222 as viewed in the first direction z, and a large part of the bonding layer 29 stays on the second surface 222 and is solidified in this state. Thus, according to this configuration, the semiconductor device A10 can suppress excessive wetting and spreading of the bonding layer 29.

The pedestal portion 22 has a first portion 22A including the first surface 221, and a second portion 22B including the second surface 222 and connected to the first portion 22A. The degree of erosion of the second portion 22B caused by the bonding layer 29 is smaller than that of erosion of the first portion 22A caused by the bonding layer 29. As an example of this configuration, the first portion 22A may contain copper, and the second portion 22B may contain nickel. With this configuration, when the electrode 41 of the semiconductor element 40 is electrically connected to the pedestal portion 22 via the bonding layer 29, the first portion 22A is protected from erosion caused by the melted bonding layer 29. This makes it possible to maintain the shape of the pedestal portion 22.

The second portion 22B of the pedestal portion 22 protrudes from the first portion 22A of the pedestal portion 22 in a direction perpendicular to the first direction z. This configuration allows for a further increase in the area of the second surface 222 of the pedestal portion 22. This makes it possible to improve the bonding strength of the electrode 41 of the semiconductor element 40 with respect to the pedestal portion 22.

The second portion 22B of the pedestal portion 22 includes a third surface 223 facing the obverse surface 21 of the conductive layer 20 in the first direction z. As viewed in the first direction z, the third surface 223 is positioned outside the interface between the first portion 22A and the second portion 22B of the pedestal portion 22. This configuration allows for a further increase in the area of the second surface 222 of the pedestal portion 22.

The first portion 22A of the pedestal portion 22 includes a fourth surface 224 positioned between the first surface 221 and the third surface 223 in the first direction z. The fourth surface 224 is curved toward the inside of the first portion 22A. The semiconductor device A10 further includes a sealing resin 50 covering the semiconductor element 40. The sealing resin 50 covers the fourth surface 224. With this configuration, the sealing resin 50 exerts an anchoring effect on the pedestal portion 22. This makes it possible to suppress peeling at the interface between the pedestal portion 22 and the sealing resin 50, which is caused by heat generated from the semiconductor element 40.

In the above example, the third surface 223 of the pedestal portion 22 overlaps with the first surface 221 of the pedestal portion 22 as viewed in the first direction z. This configuration is obtained when the degree of curvature of the fourth surface 224 of the pedestal portion 22 is larger. Thus, this configuration enhances the anchoring effect of the sealing resin 50 on the pedestal portion 22.

The second portion 22B of the pedestal portion 22 includes a fifth surface 225 facing in a direction perpendicular to the first direction z. The bonding layer 29 is in contact with the fifth surface 225. This configuration is obtained when the volume of the bonding layer 29 is relatively large. Thus, this configuration indicates that excessive wetting and spreading of the bonding layer 29 is suppressed by the pedestal portion 22 even when the volume of the bonding layer 29 is larger.

The semiconductor device A10 further includes a substrate 10 supporting the conductive layer 20, and a terminal 30 accommodated in the substrate 10 and connected to the conductive layer 20. The terminal 30 is exposed from a reverse surface 12 of the substrate 10. In this example, the semiconductor device A10 further includes a covering layer 60 that covers a part of the terminal 30 exposed from the substrate 10. The covering layer 60 is electrically conductive. The composition of the covering layer 60 includes gold. This configuration improves the wettability of melted solder with respect to the covering layer 60 when the semiconductor device A10 is mounted onto a wiring board. This makes it possible to prevent a decrease in the bonding strength of the semiconductor device A10 with respect to the wiring board.

In the above example, the terminal 30 is also exposed from a first side surface 13 of the substrate 10. The covering layer 60 also covers a part of the terminal 30 exposed from the first side surface 13. With this configuration, melted solder can easily climb up the covering layer 60 in the first direction z when the semiconductor device A10 is mounted onto a wiring board. This facilitates the formation of a solder fillet. Thus, the bonding strength of the semiconductor device A10 with respect to the wiring board can be improved. Since the solder fillet is exposed to the outside when the semiconductor device A10 is mounted onto the wiring board, the mount state of the semiconductor device A10 with respect to the wiring board can be easily checked by external inspection.

The semiconductor device A10 includes four terminals 30 located at four corners of the substrate 10 as viewed in the first direction z. Each of the four terminals 30 has an inclined end surface 33. The inclined end surface 33 is covered with the sealing resin 50. With this configuration, the volume of solder that adheres to each of the four terminals 30 can be reduced when the semiconductor device A10 is mounted onto a wiring board. This makes it possible to reduce the concentration of thermal stress generated in the four terminals 30.

### Second Embodiment

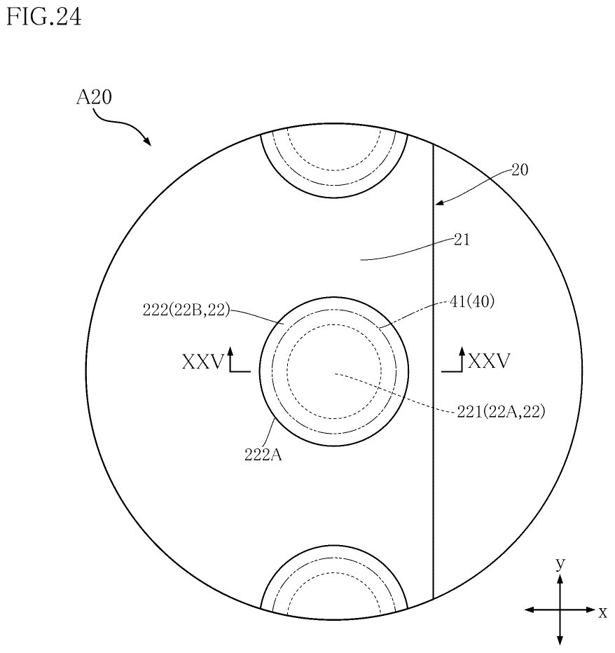

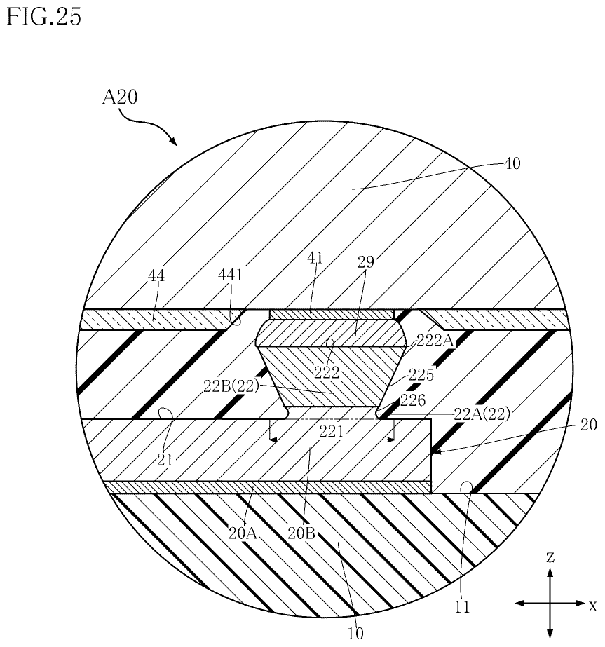

The following describes a semiconductor device A20 according to a second embodiment of the present disclosure, with reference to FIGS. 24 and 25. In these figures, elements that are the same as or similar to the elements of the semiconductor device A10 described above are provided with the same reference numerals, and descriptions thereof are omitted. For convenience of understanding, FIG. 24 omits the illustration of the semiconductor element 40 and the sealing resin 50. FIG. 24 corresponds to FIG. 7 that shows the semiconductor device A10.

The semiconductor device A20 is different from the semiconductor device A10 in the configuration of the pedestal portion 22 of each conductive layer 20.

As shown in FIGS. 24 and 25, the second portion 22B of the pedestal portion 22 has the shape of an inverted frustum. In the semiconductor device A20, the second portion 22B has the shape of an inverted truncated cone. The fifth surface 225 of the second portion 22B is inclined to the first direction z. The fifth surface 225 extends from the interface between the first portion 22A and the second portion 22B to the second surface 222 in the first direction z, and is inclined to the outside of the first surface 221 in a direction perpendicular to the first direction z. The fifth surface 225 is exposed from the bonding layer 29. The fifth surface 225 is covered with the sealing resin 50.

As shown in FIG. 25, the first portion 22A of the pedestal portion 22 has a constricted portion 226. The constricted portion 226 is recessed in a direction perpendicular to the first direction z. The sealing resin 50 is embedded in the constricted portion 226.

The second portion 22B of the pedestal portion 22 can be formed by lithographic patterning having an inverted frustum-shaped opening in the step shown in FIG. 16 in the manufacturing process of the semiconductor device A10. The constricted portion 226 of the first portion 22A of the pedestal portion 22 is formed in the step shown in FIG. 17 in the manufacturing process of the semiconductor device A10.

The following describes advantages of the semiconductor device A20.

The semiconductor device A20 includes a conductive layer 20 having an obverse surface 21 and a pedestal portion 22, a semiconductor element 40 having an electrode 41, and a bonding layer 29 electrically bonding the conductive layer 20 and the electrode 41. The bonding layer 29 includes a portion located between the pedestal portion 22 and the electrode 41. The pedestal portion 22 has a first surface 221 that is an interface with the obverse surface 21, and a second surface 222 that faces the same side as the obverse surface 21 in the first direction z and that is in contact with the bonding layer 29. The area of the second surface 222 is larger than that of the first surface 221. As viewed in the first direction z, a periphery 222A of the second surface 222 surrounds the first surface 221. Thus, according to this configuration, the semiconductor device A20 can also suppress excessive wetting and spreading of the bonding layer 29. Further, the semiconductor device A20 has configurations similar to the semiconductor device A10, thereby achieving the same advantages as the semiconductor device A10.

In the semiconductor device A20, the second portion 22B of the pedestal portion 22 has the shape of an inverted frustum. With this configuration, when the electrode 41 of the semiconductor element 40 is electrically bonded to the pedestal portion 22 via the bonding layer 29, the melted bonding layer 29 is subjected to an even larger surface tension at the periphery 222A of the second surface 222 than in the case of the semiconductor device A10. Thus, the semiconductor device A20 can effectively suppress excessive wetting and spreading of the bonding layer 29.

The first portion 22A of the pedestal portion 22 has a constricted portion 226 perpendicular to the first direction z. The sealing resin 50 is embedded in the constricted portion 226. With this configuration, the sealing resin 50 exerts an anchoring effect on the pedestal portion 22. This makes it possible to suppress peeling at the interface between the pedestal portion 22 and the sealing resin 50, which is caused by heat generated from the semiconductor element 40.

### Third Embodiment

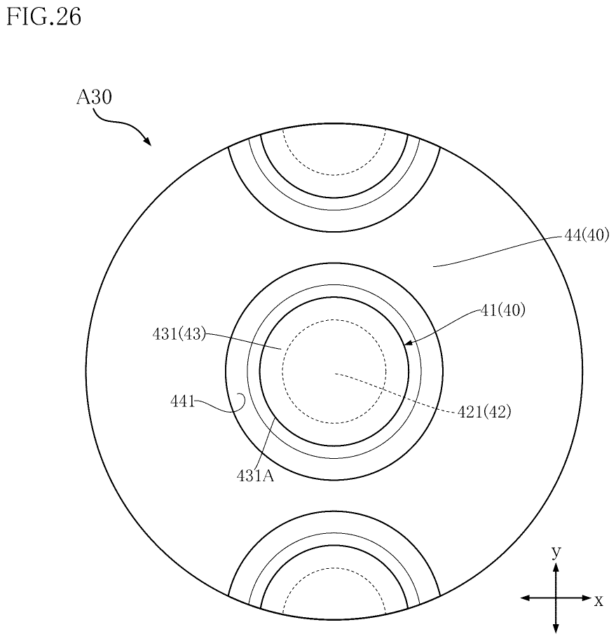

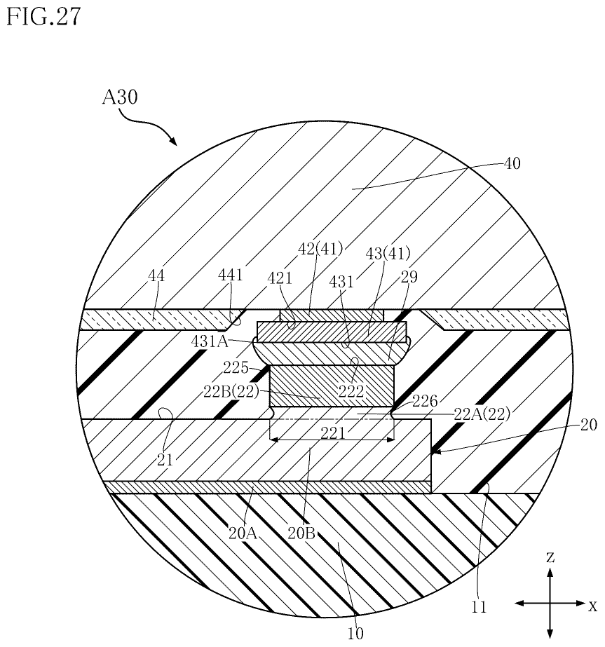

The following describes a semiconductor device A30 according to a third embodiment of the present disclosure, with reference to FIGS. 26 and 27. In these figures, elements that are the same as or similar to the elements of the semiconductor device A10 described above are provided with the same reference numerals, and descriptions thereof are omitted. FIG. 27 corresponds to FIG. 8 that shows the semiconductor device A10.

The semiconductor device A30 is different from the semiconductor device A10 in the configuration of the pedestal portion 22 of each conductive layer 20 and in the configuration of the electrodes 41 of the semiconductor element 40.

As shown in FIG. 27, the area of the second surface 222 of the pedestal portion 22 is substantially the same as the area of the first surface 221 of the pedestal portion 22.

As shown in FIG. 27, each of the electrodes 41 of the semiconductor element 40 has a base 42 and a protrusion 43. The base 42 has a base surface 421. The base surface 421 faces one of the conductive layers 20 in the first direction z. The base 42 contains copper, for example. The protrusion 43 protrudes from the base surface 421 and is connected to the base 42. The protrusion 43 protrudes from the base 42 in a direction perpendicular to the first direction z. The protrusion 43 extends outward from one of the openings 441 of the passivation film 44. The protrusion 43 contains nickel.

As shown in FIG. 27, the protrusion 43 has a bonding surface 431. The bonding surface 431 faces the same side as the base surface 421 of the base 42 in the first direction z. The area of the bonding surface 431 is larger than that of the base surface 421. As viewed in the first direction z, a periphery 431A of the bonding surface 431 surrounds the base surface 421.

As shown in FIG. 27, the bonding layer 29 includes a portion located between the second portion 22B of the pedestal portion 22 of one of the conductive layers 20 and the protrusion 43 of one of the electrodes 41. The bonding layer 29 is in contact with the bonding surface 431 of the protrusion 43. The degree of erosion of the protrusion 43 caused by the bonding layer 29 is smaller than that of erosion of the base 42 caused by the bonding layer 29.

As shown in FIG. 27, the sealing resin 50 includes a portion that indents toward the base 42 from the protrusion 43 in a direction perpendicular to the first direction z.

The following describes advantages of the semiconductor device A30.

The semiconductor device A30 includes a conductive layer 20, a semiconductor element 40 having an electrode 41, and a bonding layer 29 electrically bonding the conductive layer 20 and the electrode 41. The electrode 41 has a base surface 421 and a protrusion 43. The bonding layer 29 includes a portion located between the conductive layer 20 and the protrusion 43. The protrusion 43 has a bonding surface 431 that faces the same side as the base surface 421 in the first direction z and that is in contact with the bonding layer 29. The area of the bonding surface 431 is larger than that of the base surface 421. As viewed in the first direction z, a periphery 431A of the bonding surface 431 surrounds the base surface 421. With this configuration, when the electrode 41 is electrically bonded to the conductive layer 20 via the bonding layer 29, the melted bonding layer 29 is subjected to a larger surface tension at the periphery 431A of the bonding surface 431. This prevents the melted bonding layer 29 from overflowing from the periphery 431A of the bonding surface 431 as viewed in the first direction z, and a large part of the bonding layer 29 stays on the bonding surface 431 and is solidified in this state. Thus, according to this configuration, the semiconductor device A30 can also suppress excessive wetting and spreading of the bonding layer 29. Further, the semiconductor device A30 has configurations similar to the semiconductor device A10, thereby achieving the same advantages as the semiconductor device A10.

In the semiconductor device A30, a sealing resin 50 includes a portion that indents toward the base 42 of the electrode 41 from the protrusion 43 in a direction perpendicular to the first direction z. With this configuration, the sealing resin 50 exerts an anchoring effect on the electrode 41. This makes it possible to suppress peeling at the interface between the electrode 41 and the sealing resin 50, which is caused by heat generated from the semiconductor element 40.

The present disclosure is not limited to the above embodiments. Various design changes can be made to the specific configurations of the elements of the present disclosure.

The present disclosure includes the embodiments described in the following clauses.
Clause 1.
A semiconductor device comprising:
   a conductive layer;
   a semiconductor element including an electrode located on one side in a first direction; and
   a bonding layer electrically bonding the conductive layer and the electrode,
   wherein the conductive layer includes an obverse surface facing the semiconductor element in the first direction, and a pedestal portion protruding from the obverse surface,
   the bonding layer includes a portion located between the pedestal portion and the electrode,
   the pedestal portion includes a first surface that is an interface with the obverse surface, and a second surface that faces a same side as the obverse surface in the first direction and that is in contact with the bonding layer,
   an area of the second surface is larger than an area of the first surface, and
   as viewed in the first direction, a periphery of the second surface surrounds the first surface.
Clause 2.
A semiconductor device comprising:
   a conductive layer;
   a semiconductor element including an electrode located on one side in a first direction; and
   a bonding layer electrically bonding the conductive layer and the electrode,
   wherein the electrode includes a base surface facing the conductive layer in the first direction, and a protrusion protruding from the base surface,
   the bonding layer includes a portion located between the conductive layer and the protrusion,
   the protrusion includes a bonding surface that faces a same side as the base surface in the first direction, and that is in contact with the bonding layer,
   an area of the bonding surface is larger than an area of the base surface, and
   as viewed in the first direction, a periphery of the bonding surface surrounds the base surface.
Clause 3.
The semiconductor device according to clause 1, wherein the pedestal portion includes a first portion including the first surface, and a second portion including the second surface and connected to the first portion, and
   a degree of erosion of the second portion caused by the bonding layer is smaller than a degree of erosion of the first portion caused by the bonding layer.
Clause 4.
The semiconductor device according to clause 3, wherein the second portion protrudes from the first portion in a direction perpendicular to the first direction.
Clause 5.
The semiconductor device according to clause 3, wherein the second portion has a shape of an inverted frustum.
Clause 6.
The semiconductor device according to clause 4, wherein the second portion includes a third surface that faces the obverse surface in the first direction, and that is positioned outside an interface between the first portion and the second portion as viewed in the first direction, and the third surface is exposed from the bonding layer.
Clause 7.
The semiconductor device according to clause 6, wherein the first portion includes a fourth surface located between the first surface and the third surface in the first direction, and the fourth surface is curved toward an inside of the first portion.
Clause 8.
The semiconductor device according to clause 7, wherein the third surface overlaps with the first surface as viewed in the first direction.
Clause 9.
The semiconductor device according to any of clauses 6 to 8, wherein the second portion includes a fifth surface facing in a direction perpendicular to the first direction, and the bonding layer is in contact with the fifth surface.
Clause 10.
The semiconductor device according to clause 5, wherein the first portion includes a constricted portion recessed in a direction perpendicular to the first direction.
Clause 11.
The semiconductor device according to clause 4 or 5, wherein the first portion contains copper, and
   the second portion contains nickel.
Clause 12.
The semiconductor device according to clause 11, further comprising a sealing resin covering the semiconductor element,
   wherein the sealing resin is in contact with the bonding layer.
Clause 13.
The semiconductor device according to clause 12, further comprising a substrate supporting the conductive layer and the sealing resin.
Clause 14.
The semiconductor device according to clause 13, wherein the conductive layer includes an underlying layer in contact with the substrate, and a body layer stacked on the underlying layer,
   the body layer includes the obverse surface and is connected to the pedestal portion,
   the underlying layer contains titanium, and
   the body layer contains copper.
Clause 15.
The semiconductor device according to clause 14, further comprising a terminal connected to the conductive layer, and
   a part of the terminal is accommodated in the substrate.
Clause 16.
The semiconductor device according to clause 15, wherein the terminal includes an exposed surface facing in a direction perpendicular to the first direction, and the exposed surface is exposed from the substrate.
Clause 17.
A method for manufacturing a semiconductor device, comprising:
   a step of forming a conductive layer; and
   a step of electrically bonding a semiconductor element to the conductive layer,
   wherein the step of forming the conductive layer includes a step of forming a body layer, and a step of forming a pedestal portion protruding from the body layer in the first direction,
   the semiconductor element includes an electrode facing the pedestal portion,
   in the step of electrically bonding the semiconductor element to the conductive layer, the electrode is electrically bonded to the pedestal portion by reflow, and
   in the step of forming the pedestal portion, a constricted portion, which is recessed in a direction perpendicular to the first direction and connected to the body layer, is formed in the pedestal portion.
Clause 18.
The method for manufacturing a semiconductor device according to clause 17, wherein the step of forming the conductive layer includes a step of forming an underlying layer before the step of forming the body layer,
   the underlying layer contains titanium,
   the body layer contains copper,
   in the step of forming the body layer, the body layer is formed on the underlying layer by electrolytic plating, and
   in the step of forming the pedestal portion, a part of the underlying layer, which is exposed to an outside from the body layer, is removed.

### REFERENCE NUMERALS

A10, A20, A30: Semiconductor device 10: Substrate
11: Obverse surface 12: Reverse surface
20: Conductive layer 13: First side surface
20A: Underlying layer 20B: Body layer
21: Obverse surface 22: Pedestal portion
22A: First portion 22B: Second portion
221: First surface 222: Second surface
222A: Periphery 223: Third surface
224: Fourth surface 225: Fifth surface
226: Constricted portion 23: End surface
29: Bonding layer 30: Terminal
31: First exposed surface 32: Second exposed surface
33: Inclined end surface 40: Semiconductor element
41: Electrode 42: Base
421: Base surface 43: Protrusion
431: Bonding surface 431A: Periphery
44: Passivation film 441: Opening
50: Sealing resin 51: Top surface
52: Second side surface 521: First region
522: Second region 60: Covering layer
81: Support member 82: Intermediate layer
83: Terminal layer 84: First resin layer
85: Conductive layer 851: Underlying layer
852: Body layer 853: Pedestal portion
854: Protruding layer 855: Constricted portion
86: Second resin layer 861: Groove
88: Tape 891: First blade
892: Second blade z: First direction
x: Second direction y: Third direction

1. A semiconductor device comprising:
a conductive layer;
a semiconductor element including an electrode located on one side in a first direction; and
a bonding layer electrically bonding the conductive layer and the electrode,
wherein the conductive layer includes an obverse surface facing the semiconductor element in the first direction, and a pedestal portion protruding from the obverse surface,
the bonding layer includes a portion located between the pedestal portion and the electrode,
the pedestal portion includes a first surface that is an interface with the obverse surface, and a second surface that faces a same side as the obverse surface in the first direction and that is in contact with the bonding layer,
an area of the second surface is larger than an area of the first surface, and
as viewed in the first direction, a periphery of the second surface surrounds the first surface.

2. A semiconductor device comprising:
a conductive layer;
a semiconductor element including an electrode located on one side in a first direction; and
a bonding layer electrically bonding the conductive layer and the electrode,
wherein the electrode includes a base surface facing the conductive layer in the first direction, and a protrusion protruding from the base surface,
the bonding layer includes a portion located between the conductive layer and the protrusion,
the protrusion includes a bonding surface that faces a same side as the base surface in the first direction, and that is in contact with the bonding layer,
an area of the bonding surface is larger than an area of the base surface, and
as viewed in the first direction, a periphery of the bonding surface surrounds the base surface.

3. The semiconductor device according to claim 1, wherein the pedestal portion includes a first portion including the first surface, and a second portion including the second surface and connected to the first portion, and
a degree of erosion of the second portion caused by the bonding layer is smaller than a degree of erosion of the first portion caused by the bonding layer.

4. The semiconductor device according to claim 3, wherein the second portion protrudes from the first portion in a direction perpendicular to the first direction.

5. The semiconductor device according to claim 3, wherein the second portion has a shape of an inverted frustum.

6. The semiconductor device according to claim 4, wherein the second portion includes a third surface that faces the obverse surface in the first direction, and that is positioned outside an interface between the first portion and the second portion as viewed in the first direction, and
the third surface is exposed from the bonding layer.

7. The semiconductor device according to claim 6, wherein the first portion includes a fourth surface located between the first surface and the third surface in the first direction, and
the fourth surface is curved toward an inside of the first portion.

8. The semiconductor device according to claim 7, wherein the third surface overlaps with the first surface as viewed in the first direction.

9. The semiconductor device according to claim 6, wherein the second portion includes a fifth surface facing in a direction perpendicular to the first direction, and
the bonding layer is in contact with the fifth surface.

10. The semiconductor device according to claim 5, wherein the first portion includes a constricted portion recessed in a direction perpendicular to the first direction.

11. The semiconductor device according to claim 4, wherein the first portion contains copper, and
the second portion contains nickel.

12. The semiconductor device according to claim 11, further comprising a sealing resin covering the semiconductor element,
wherein the sealing resin is in contact with the bonding layer.

13. The semiconductor device according to claim 12, further comprising a substrate supporting the conductive layer and the sealing resin.

14. The semiconductor device according to claim 13, wherein the conductive layer includes an underlying layer in contact with the substrate, and a body layer stacked on the underlying layer,
the body layer includes the obverse surface and is connected to the pedestal portion,
the underlying layer contains titanium, and
the body layer contains copper.

15. The semiconductor device according to claim 14, further comprising a terminal connected to the conductive layer, and
a part of the terminal is accommodated in the substrate.

16. The semiconductor device according to claim 15, wherein the terminal includes an exposed surface facing in a direction perpendicular to the first direction, and
the exposed surface is exposed from the substrate.

17. A method for manufacturing a semiconductor device, comprising:
a step of forming a conductive layer; and
a step of electrically bonding a semiconductor element to the conductive layer,
wherein the step of forming the conductive layer includes a step of forming a body layer, and a step of forming a pedestal portion protruding from the body layer in the first direction,
the semiconductor element includes an electrode facing the pedestal portion,
in the step of electrically bonding the semiconductor element to the conductive layer, the electrode is electrically bonded to the pedestal portion by reflow, and
in the step of forming the pedestal portion, a constricted portion, which is recessed in a direction perpendicular to the first direction and connected to the body layer, is formed in the pedestal portion.

18. The method for manufacturing a semiconductor device according to claim 17,
wherein the step of forming the conductive layer includes a step of forming an underlying layer before the step of forming the body layer,
the underlying layer contains titanium,
the body layer contains copper,
in the step of forming the body layer, the body layer is formed on the underlying layer by electrolytic plating, and
in the step of forming the pedestal portion, a part of the underlying layer, which is exposed to an outside from the body layer, is removed.
